(19) United States
(12) Patent Application Publication
(10) Pub. No.: US 2007/0138620 A1
(43) Pub. Date: Jun. 21, 2007

(54) COMPOSITE FLOW BOARD FOR FUEL CELL

(76) Inventors: Hsi-Ming Shu, Taipei (TW); Tsang-Ming Chang, Taipei (TW); Wei-Li Huang, Taipei (TW)

Correspondence Address: G. LINK CO., LTD., 3550 BELL ROAD, MINOOKA, IL, 60447, US

(21) Appl. No.: 11/611,870

(22) Filed: Dec. 17, 2006

(30) Foreign Application Priority Data
Dec. 19, 2005 (TW) 094222129

(51) Int. Cl. H01L 23/053; H01L 23/12

(52) U.S. Cl. 257/701

(57) ABSTRACT

A composite flow board for a fuel cell is disclosed, which includes a first substrate, a second substrate and at least one third substrate. The first substrate is made of plasticized material in the form of a plate. The first substrate includes one or more concave portions spaced apart from one another. The concave portions are formed on a surface of the first substrate. The second substrate is made of well-adhesive material in the form of a framework. The second substrate includes four frames and a hollow portion. The space inside the hollow portion is used to contain the first substrate, and the first substrate is connected with the four frames. The third substrate is made of metal in the form of a thin layer. The third substrate is shaped to the concave portions, and is attached to the concave portions.

### FIELD OF THE INVENTION

The present invention relates to a flow board for a fuel cell, and more particularly, to a composite flow board for a fuel cell.

### BACKGROUND OF THE INVENTION

The prior art concerning flow boards of fuel cells has usually emphasized modifying the structure of flow channels, in order to smoothly flow fuels into membrane electrode assemblies (MEAs) through the flow channels. In addition, the conventional flow board is made from only one kind of substrate.

### SUMMARY OF THE INVENTION

It is a primary object of the invention to provide a composite flow board. Using such a composite flow board may solve the issue of the non-uniform temperature profile of fuels supplied for electrode membrane assemblies, so as to enhance the efficiency of power generation by a fuel cell.

It is a secondary object of the invention to provide a composite flow board, which is anticorrosive and acid-proof. Hence, the flow board is protected from being damaged by fuels or products generated during electrochemical reactions.

It is a third object of the invention to provide a composite flow board that combines at least two materials. Taking advantage of the physical properties of these materials may reduce the cost of fabrication, and improve the connection of the flow board to a current collection layer or plate.

In accordance with the aforesaid objects of the invention, a composite flow board for a fuel cell is provided, which includes a first substrate, a second substrate and at least one third substrate. The first substrate is made of plasticized material in the form of a plate. The first substrate includes one or more concave portions spaced apart from one another. The concave portions are formed on a surface of the first substrate. The second substrate is made of a well-adhesive material in the form of a framework. The second substrate includes four frames and a hollow portion. The space inside the hollow portion is used to contain the first substrate, and the first substrate is connected with the four frames. The third substrate is made of metal in the form of a thin layer. The third substrate is shaped to the concave portions, and is attached to the concave portions.

### BRIEF DESCRIPTION OF THE DRAWINGS

The foregoing aspects, as well as many of the attendant advantages and features of this invention will become more apparent by reference to the following detailed description, when taken in conjunction with the accompanying drawings, wherein:

FIG. 1 is an exploded diagram showing a composite flow board for a fuel cell according to the first embodiment of the invention;

FIG. 2 is the top view of a composite flow board for a fuel cell according to the first embodiment of the invention;

FIG. 3 is an exploded diagram showing a composite flow board for a fuel cell according to the second embodiment of the invention;

FIG. 4 is the top view of a composite flow board for a fuel cell according to the second embodiment of the invention;

FIG. 5 is an exploded diagram showing a composite flow board for a fuel cell according to the third embodiment of the invention; and

FIG. 6 is the top view of a composite flow board for a fuel cell according to the third embodiment of the invention.

### DETAILED DESCRIPTION OF THE INVENTION

### 1st Embodiment

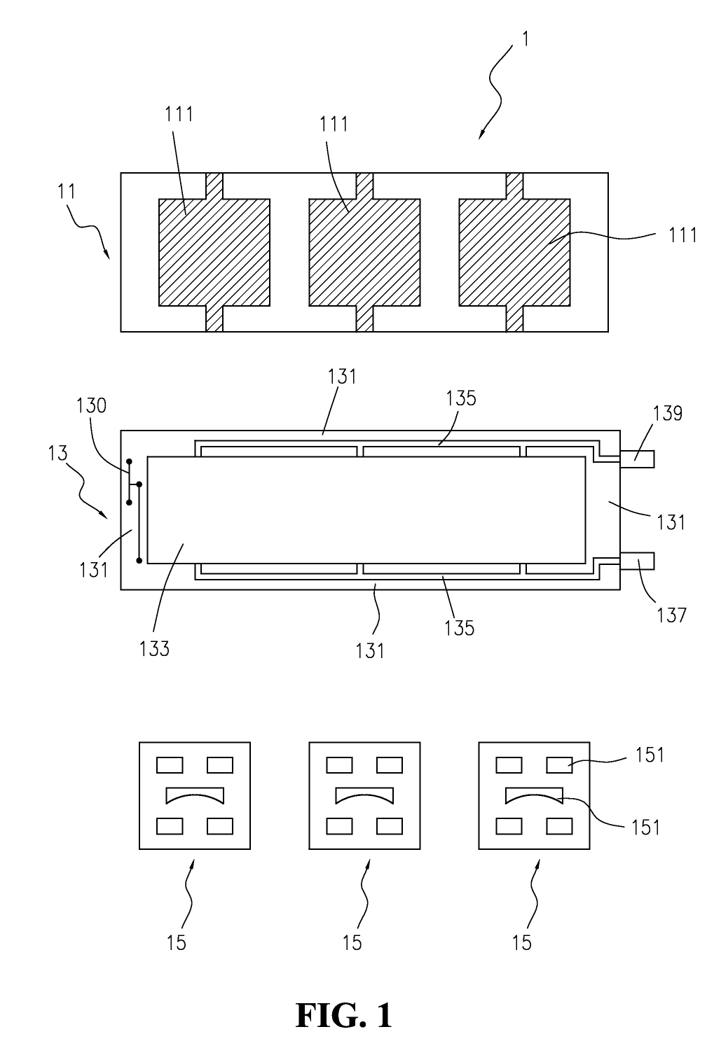

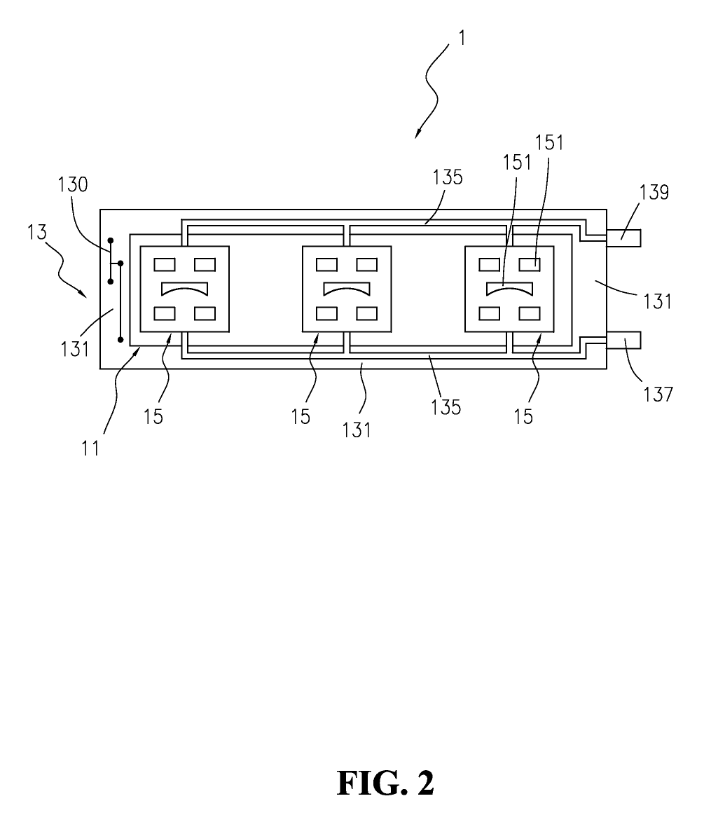

FIG. 1 is an exploded diagram showing a composite flow board for a fuel cell according to the first embodiment of the invention. FIG. 2 is the top view of a composite flow board for a fuel cell according to the first embodiment of the invention. In the first embodiment, a composite flow board 1 for a fuel cell includes a first substrate 11, a second substrate 13 and a third substrate 15, which are separately described hereinafter. The first substrate 11 is made of plasticized material that facilitates the flexible and easy process of manufacturing the first substrate 11 so as to reduce the cost of fabrication. The first substrate 11 may be selected from a group consisting of a plastic substrate, a ceramic substrate, a printed circuit substrate, a polymeric plastic substrate, or a composite substrate thereof.

The first substrate 11 is in the form of a plate. One or more concave portions 111 are disposed on the surface of the first substrate 11, and are spaced apart at a predetermined distance. Also, the concave portions 111 are positioned respectively corresponding to the membrane electrode assemblies.

The second substrate 13 is made from well-adhesive material, for the adhesion property required by the second substrate 13 itself. Since the second substrate 13 is well-adhesive, it can be attached and sealed to a current collection layer or plate (not shown). The second substrate 13 may adopt a plastic substrate, a ceramic substrate, a printed circuit substrate, a polymeric plastic substrate, or a composite substrate thereof.

The second substrate 13 is in the form of a framework. The second substrate 13 includes four frames 131 and a hollow portion 133. The space inside the hollow portion 133 is used to contain the first substrate 11, and the first substrate 11 is connected with the four frames 131.

The second substrate 13 further includes a flow channel structure 135, a fuel inlet 137 and a fuel outlet 139. The flow channel structure 135 is composed of a plurality of trenches dug through the surface of the frames 131. Fuels out of the fuel inlet 137 may pass through the concave portions 111 via the flow channel structure 135, and flow out from the fuel outlet 139. The fuel inlet 137 and the fuel outlet 139 are disposed on one side of the second substrate 13. Additionally, the fuel inlet 137 and the fuel outlet 139 are in fluid communication with the flow channel structure 135.

The third substrate 15 is made of metal, so the third substrate 15 conducts both heat and electricity well. Thus, fuels within the concave portions 111 are distributed at a uniform temperature. The third substrate 15 may utilize metal, such as aluminum, copper, aluminum alloy, copper alloy, stainless steel, gold, etc., or other mono-metal or other metal alloy. Moreover, the surface of the third substrate 15 contacting fuels may be further treated by an anticorrosive process or an acid-proof process. For example, the surface of the third substrate 15 is coated with a layer of Teflon or plated with a lamina of gold. As a result, the third substrate 15 is protected from being damaged by fuels or products generated during electrochemical reactions.

The third substrate 15 is in the form of a thin layer. The third substrate 15 is shaped to the concave portions 111, and is attached to the concave portions 111.

Furthermore, a circuit layout 130 may be formed on the surface of any one of the frames 131 or on the surfaces of all of the frames 131 for conducting electricity. Alternatively, some electronic elements may be soldered on the circuit layout to constitute a circuit.

The first substrate 11, the second substrate 13 and the third substrate 15 of the first embodiment are then assembled together. As shown in FIG. 2, the resultant composite flow board 1 appears to be a one-piece structure.

### 2nd Embodiment

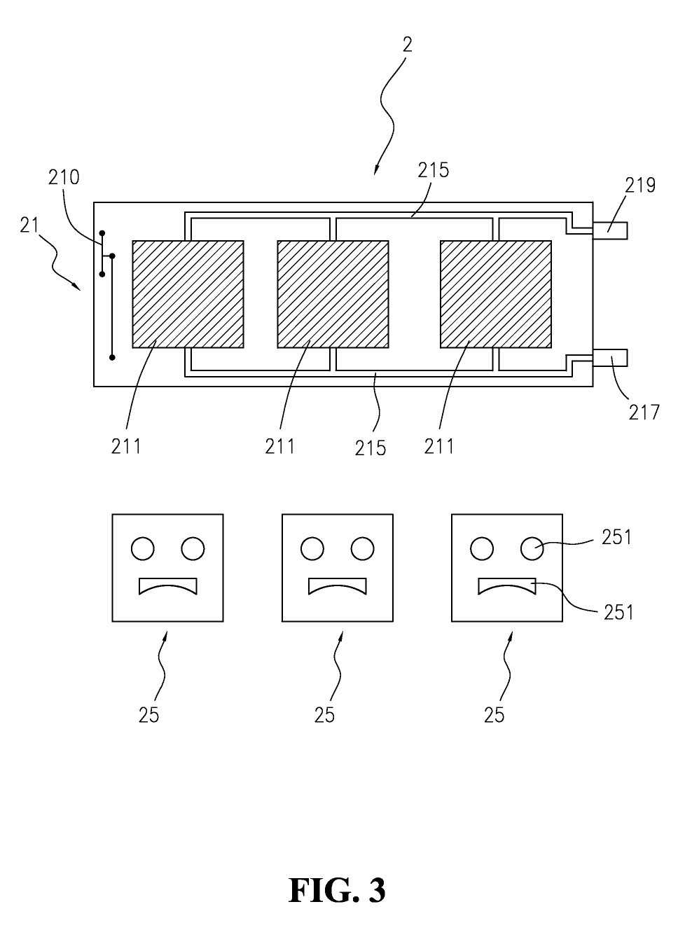

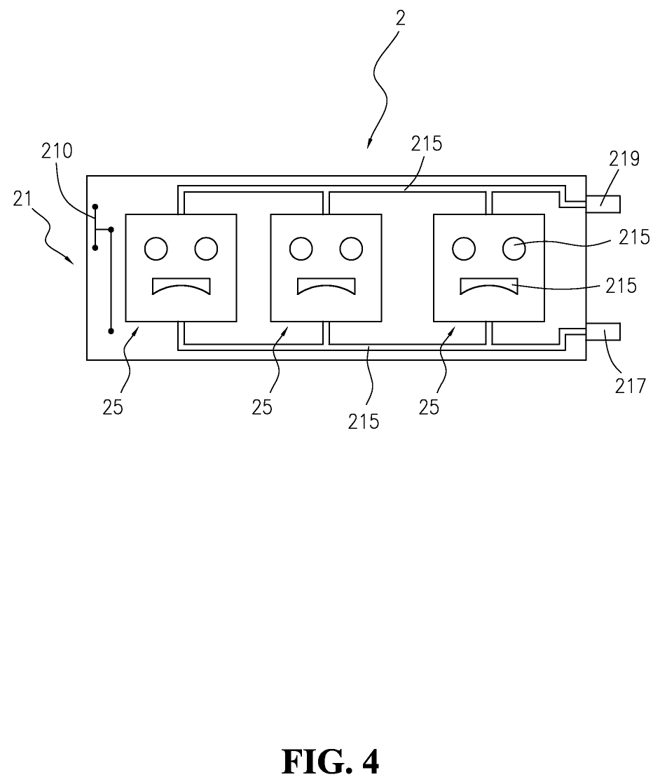

FIG. 3 is an exploded diagram showing a composite flow board for a fuel cell according to the second embodiment of the invention. FIG. 4 is the top view of a composite flow board for a fuel cell according to the second embodiment of the invention. In the second embodiment, a composite flow board 2 for a fuel cell includes a first substrate 21 and a third substrate 25, which are separately described hereinafter.

The first substrate 21 is made of well-adhesive material, for the adhesion property required by the first substrate 21 itself. Since the first substrate 21 is well-adhesive, it can be attached and sealed to a current collection layer or plate (not shown). The first substrate 21 may adopt a plastic substrate, a ceramic substrate, a printed circuit substrate, a polymeric plastic substrate, or a composite substrate thereof.

The first substrate 21 is in the form of a plate. One or more concave portions 211 are disposed on the surface of the first substrate 21, and are spaced apart at a predetermined distance. Also, the concave portions 211 are positioned respectively corresponding to the membrane electrode assemblies.

Also, the first substrate 21 includes a flow channel structure 215, a fuel inlet 217 and a fuel outlet 219. The flow channel structure 215 is composed of a plurality of trenches dug through the surface of the first substrate 21. Fuels flowing out of the fuel inlet 217 may pass through the concave portions 211 via the flow channel structure 215, and flow out from the fuel outlet 219. The fuel inlet 217 and the fuel outlet 219 are disposed on one side of the first substrate 21. Additionally, the fuel inlet 217 and the fuel outlet 219 are in fluid communication with the flow channel structure 215.

A circuit layout 210 may be further formed on the surface of the first substrate 21 for conducting electricity. Alternatively, some electronic elements may be soldered on the circuit layout to constitute a circuit.

The third substrate 25 is made of metal, so the third substrate 25 conducts both heat and electricity well. Thus, fuels within the concave portions 211 are distributed at a uniform temperature. The third substrate 25 may utilize metal, such as aluminum, copper, aluminum alloy, copper alloy, stainless steel, gold, etc., or other mono-metal or other metal alloy. Moreover, the surface of the third substrate 25 contacting fuels may be treated by an anticorrosive process or an acid-proof process. For example, the surface of the third substrate 25 is coated with a layer of Teflon or plated with a lamina of gold. As a result, the third substrate 25 is protected from being damaged by fuels or products generated during electrochemical reactions.

The third substrate 25 is in the form of a thin layer. The third substrate 25 is shaped to the concave portions 211, and is attached to the concave portions 211.

The first substrate 21 and the third substrate 25 of the second embodiment are then assembled together. As shown in FIG. 4, the resultant composite flow board 2 appears to be a one-piece structure.

### 3rd Embodiment

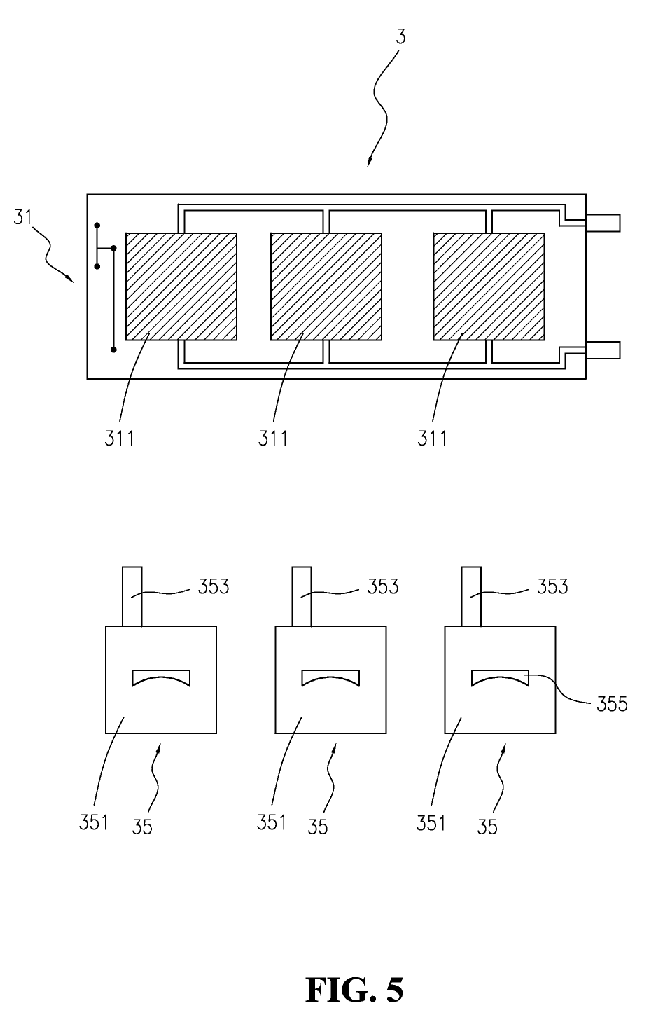

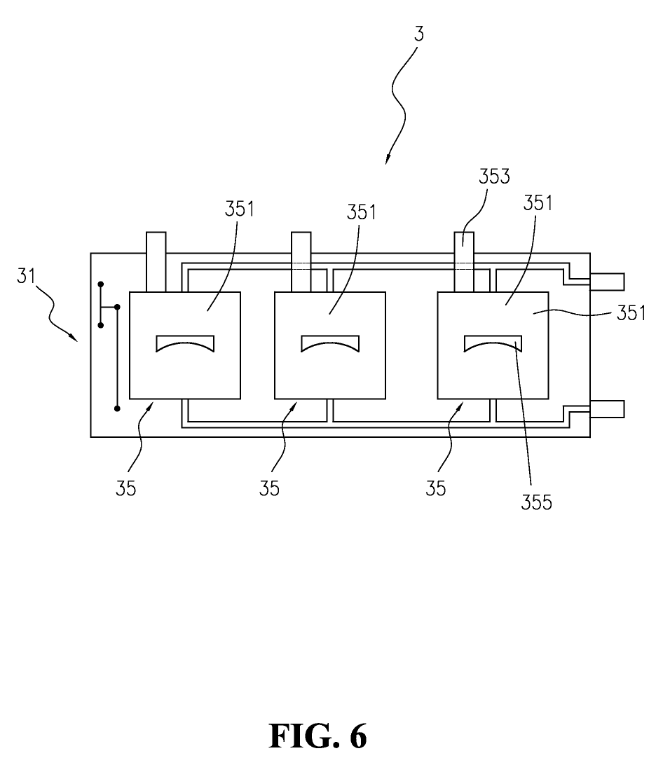

FIG. 5 is an exploded diagram showing a composite flow board for a fuel cell according to the third embodiment of the invention. FIG. 6 is the top view of a composite flow board for a fuel cell according to the third embodiment of the invention. In the third embodiment, a composite flow board 3 for a fuel cell includes a first substrate 31 and a third substrate 35, which are separately described hereinafter.

The first substrate 31 in the third embodiment is similar to the first substrate 21 in the second embodiment; hence, the description of the first substrate 31 is omitted herein.

The third substrate 35 is made of metal, so the third substrate 35 conducts both heat and electricity well. Thus, fuels within the concave portions 311 are distributed at a uniform temperature. The third substrate 35 may utilize metal, such as aluminum, copper, aluminum alloy, copper alloy, stainless steel, gold, etc., or other mono-metal or other metal alloy. Moreover, the surface of the third substrate 35 contacting fuels may be treated by an anticorrosive process or an acid-proof process. For example, the surface of the third substrate 35 is coated with a layer of Teflon or plated with a lamina of gold. As a result, the third substrate 35 is protected from being damaged by fuels or products generated during electrochemical reactions.

The third substrate 35 is in the form of a thin layer. The third substrate 35 has a first region 351 and a second region 353. The first region 351 is shaped to the concave portions 311, so the first region 351 is attached to the concave portions 311.

The second region 353 of the third substrate 35 protrudes into the first substrate 31, and thereby heat from the concave portions 311 is conducted outside through the second region 353.

The first substrate 31 and the third substrate 35 of the third embodiment are then assembled together. As shown in FIG. 6, the resultant composite flow board 3 appears to be a one-piece structure.

In addition, the first substrate 11 of the first embodiment includes concave portions 111 that are rectangular trenches with flat bottoms, for example. Where the concave portions 111 are rectangular trenches with flat bottoms, one or more protruding portions 151 are disposed on the third substrate 15. The protruding portions 151 are adapted to flow fuels within the concave portions 111 into the electrode membrane assemblies evenly.

In addition, the first substrate 21 of the second embodiment includes concave portions 211 that are rectangular trenches with flat bottoms, for example. Where the concave portions 211 are rectangular trenches with flat bottoms, one or more protruding portions 251 are disposed on the third substrate 25. The protruding portions 251 are adapted to flow fuels within the concave portions 211 into the electrode membrane assemblies evenly.

In addition, the first substrate 31 of the third embodiment includes concave portions 311 that are rectangular trenches with flat bottoms, for example. Where the concave portions 311 are rectangular trenches with flat bottoms, one or more protruding portions 355 are disposed in the first region 351 of the third substrate 35. The protruding portions 355 are adapted to flow fuels within the concave portions 311 into the electrode membrane assemblies evenly.

The aforementioned concave portions 111, 211, 311 may be constructed as a wavy structure with several continuous waves, a honeycomb structure, or a serpentine structure with a raised strip zigzagging on the concave portions 111, 211, 311.

The composite flow board combines the physical properties of various substrates, and has the characteristics of a more uniform temperature profile of fuels, better anticorrosion/acid proof performance, and stronger adhesion to a current collection layer or plate. Therefore, the composite flow board is superior to a conventional flow board that is made from only one kind of material.

While the invention has been particularly shown and described with reference to the preferred embodiments thereof, these are, of course, merely examples to help clarify the invention and are not intended to limit the invention. It will be understood by those skilled in the art that various changes, modifications, and alterations in form and details may be made therein without departing from the spirit and scope of the invention, as set forth in the following claims.

What is claimed is:

1. A composite flow board for a fuel cell, the composite flow board comprising:
a first substrate made of a plasticized material in the form of a plate, including one or more concave portions spaced apart from one another, wherein the concave portions are formed on a surface of the first substrate;
a second substrate made of a well-adhesive material in the form of a framework, including four frames and a hollow portion, wherein a space inside the hollow portion contains the first substrate, and the first substrate is connected with the four frames;
a third substrate made from at least one metal in the form of a thin layer, wherein the third substrate is shaped to the concave portions, and the third substrate is attached to the concave portions.

2. The composite flow board of claim 1, wherein the first substrate is selected from a group consisting of a plastic substrate, a ceramic substrate, a printed circuit substrate, a polymeric plastic substrate, and a composite substrate thereof.

3. The composite flow board of claim 1, wherein the second substrate is selected from a group consisting of a plastic substrate, a ceramic substrate, a printed circuit substrate, a polymeric plastic substrate, and a composite substrate thereof.

4. The composite flow board of claim 1, wherein the second substrate further comprises a flow channel structure, a fuel inlet and a fuel outlet, wherein the fuel inlet and the fuel outlet are disposed on a side of the second substrate, and the flow channel structure is disposed on a surface of the frames.

5. The composite flow board of claim 1, wherein the second substrate further comprises a circuit layout deployed on a surface of the frames.

6. The composite flow board of claim 1, wherein the third substrate is composed of a material selected from a group consisting of aluminum, copper, aluminum alloy, copper alloy, stainless steel, gold, other mono-metal, and other metal alloy.

7. The composite flow board of claim 1, wherein a surface of the third substrate is a metallic surface treated by an anticorrosive process and/or an acid-proof process.

8. A composite flow board for a fuel cell, the composite flow board comprising:
a first substrate made of a well-adhesive material in the form of a plate, including one or more concave portions spaced apart from one another, wherein the concave portions are formed on a surface of the first substrate;
a third substrate made from at least one metal in the form of a thin layer, wherein the third substrate is shaped to the concave portions, and the third substrate is attached to the concave portions.

9. The composite flow board of claim 8, wherein the first substrate is selected from a group consisting of a plastic substrate, a ceramic substrate, a printed circuit substrate, a polymeric plastic substrate, and a composite substrate thereof.

10. The composite flow board of claim 8, wherein the third substrate is composed of a material selected from a group consisting of aluminum, copper, aluminum alloy, copper alloy, stainless steel, gold, other mono-metal, and other metal alloy.

11. The composite flow board of claim 8, wherein a surface of the third substrate is a metallic surface treated by an anticorrosive process and/or an acid-proof process.

12. The composite flow board of claim 8, wherein the first substrate further comprises a flow channel structure, a fuel inlet and a fuel outlet, wherein the fuel inlet and the fuel outlet are disposed on a side of the first substrate, and the flow channel structure is disposed on a surface of the first substrate.

13. The composite flow board of claim 8, wherein the first substrate further comprises a circuit layout deployed on a surface of the first substrate.

14. A composite flow board for a fuel cell, the composite flow board comprising:
a first substrate made of a well-adhesive material in the form of a plate, including one or more concave portions spaced apart from one another, wherein the concave portions are formed on a surface of the first substrate;
a third substrate made from at least one metal in the form of a thin layer, the third substrate comprising a first region and a second region, wherein the first region is shaped to the concave portions, the first region is attached to the concave portions, and the second region protrudes into the first substrate externally.

15. The composite flow board of claim 14, wherein the first substrate is selected from a group consisting of a plastic substrate, a ceramic substrate, a printed circuit substrate, a polymeric plastic substrate, and a composite substrate thereof.

16. The composite flow board of claim 14, wherein the third substrate is composed of a material selected from a group consisting of aluminum, copper, aluminum alloy, copper alloy, stainless steel, gold, other mono-metal, and other metal alloy.

17. The composite flow board of claim 14, wherein a surface of the third substrate is a metallic surface treated by an anticorrosive process and/or an acid-proof process.

18. The composite flow board of claim 14, wherein the first substrate further comprises a flow channel structure, a fuel inlet and a fuel outlet, wherein the fuel inlet and the fuel outlet are disposed on a side of the first substrate, and the flow channel structure is disposed on a surface of the first substrate.

19. The composite flow board of claim 14, wherein the first substrate further comprises a circuit layout deployed on a surface of the first substrate.
